(19) United States
(12) Patent Application Publication
(10) Pub. No.: US 2012/0205716 A1
(43) Pub. Date: Aug. 16, 2012

(54) Epitaxially Grown Extension Regions for Scaled CMOS Devices

(75) Inventors: Thomas N. Adam, Slingerlands, NY (US); Jeffrey B. Johnson, Essex Junction, VT (US); Pranita Kulkarni, Slingerlands, NY (US); Douglas C. LaTulipe, JR., Guilderland, NY (US); Alexander Reznicek, Mount Kisco, NY (US)

(73) Assignee: INTERNATIONAL BUSINESS MACHINES CORPORATION, Armonk, NY (US)

(21) Appl. No.: 13/028,316

(22) Filed: Feb. 16, 2011

(51) Int. Cl. H01L 29/165; H01L 21/8238

(52) U.S. Cl. 257/192; 438/154; 257/E29.085; 257/E21.634

(57) ABSTRACT

Epitaxially grown extension regions are disclosed for scaled CMOS devices. Semiconductor devices are provided that comprise a field effect transistor (FET) structure having a gate stack on a silicon substrate, wherein the field effect transistor structure comprises at least a channel layer formed below the gate stack. One or more etched extension regions containing an epitaxially grown dopant are provided in the channel layer.

### FIELD OF THE INVENTION

The present invention relates generally to semiconductor devices, and, more particularly, to such semiconductor devices having epitaxy grown extension regions.

### BACKGROUND OF THE INVENTION

Conventional CMOS technology integration schemes are increasingly pushed to reduce device dimensions. For example, current integration schemes are attempting to reduce the device dimensions to 22 nanometers (nm) or less. As the device dimensions are reduced to these small values, a number of problems have been identified related to geometry effects. For example, as the device pitch is reduced to provide additional computing power (transistors) in a given chip area, the space between the gates is affected such that angled implants during ion implantation become shadowed by the gates. In addition, while it is often desirable to apply a strain under the gate in the channel region of CMOS devices to manipulate carrier mobility, the available volume in the source and drain regions of such reduced-dimension devices becomes increasingly insufficient to effectively stress the active channel. Further problems have been identified with respect to undesired dopant diffusion and increased external resistance.

A need therefore exists for a new CMOS device structure that employs a sharp extension region containing an epitaxially grown dopant.

### SUMMARY OF THE INVENTION

Generally, epitaxially grown extension regions are disclosed for scaled CMOS devices. Semiconductor devices are provided that comprise a field effect transistor (FET) structure having a gate stack on a silicon substrate, wherein the field effect transistor structure comprises at least a channel layer formed below the gate stack. According to one aspect of the invention, one or more etched extension regions containing an epitaxially grown dopant are provided in the channel layer. The silicon substrate may comprise, for example, a bulk wafer or a Silicon-On-Insulator (SOI) wafer.

In one embodiment, the channel layer comprises a silicon germanium (SiGe) region formed above the silicon substrate and below the gate stack. The SiGe region can be created, for example, by implanting germanium in a silicon layer in the silicon substrate or created epitaxially. In a further variation, the epitaxially grown dopant can optionally be combined in the extension region with a growth of a source-drain epitaxy in a trench.

The semiconductor device can be embodied, for example, on a CMOS circuit and the FET structure can comprise a pFET structure or an nFET structure.

A more complete understanding of the present invention, as well as further features and advantages of the present invention, will be obtained by reference to the following detailed description and drawings.

### BRIEF DESCRIPTION OF THE DRAWINGS

FIG. 1 illustrates a cross-sectional side view of a conventional, p-channel MOSFET (pFET) structure in which a silicon germanium (SiGe) layer is formed above a Silicon-On-Insulator (SOI) wafer;

FIG. 2 illustrates a cross-sectional view of the pFET structure of FIG. 1, following a step of a first exemplary method of forming an improved pFET structure;

FIG. 3 illustrates a cross-sectional view of the pFET structure of FIG. 2, following a subsequent step of the first exemplary method of forming an improved pFET structure;

FIG. 4 illustrates a cross-sectional view of the pFET structure of FIG. 3, following a subsequent step of the first exemplary method of forming an improved pFET structure;

FIG. 5 illustrates a cross-sectional view of a conventional, alternate p-channel MOSFET (pFET) structure, upon which a second exemplary method of the present invention may be employed;

FIG. 6 illustrates a cross-sectional view of the pFET structure of FIG. 5, following a step of the second exemplary method of forming an improved pFET structure;

FIG. 7 illustrates a cross-sectional view of the pFET structure of FIG. 6, following a subsequent step of the second exemplary method of forming an improved pFET structure;

FIG. 8 illustrates a cross-sectional view of the pFET structure of FIG. 7, following a subsequent step of the second exemplary method of forming an improved pFET structure;

FIG. 9 illustrates a cross-sectional view of the pFET structure of FIG. 8, following a subsequent step of the second exemplary method of forming an improved pFET structure;

FIG. 10 illustrates a cross-sectional view of the pFET structure of FIG. 9, following a subsequent step of the second exemplary method of forming an improved pFET structure; and

FIG. 11 illustrates a cross-sectional view of the pFET structure of FIG. 10, following a subsequent step of the second exemplary method of forming an improved pFET structure.

### DETAILED DESCRIPTION OF PREFERRED EMBODIMENTS

The present invention provides improved CMOS device structures that employ a sharp extension region. As discussed hereinafter, the present invention tailors the extension region of a CMOS device. With conventional CMOS devices, extension regions are typically heavily-doped and very shallow implanted regions that form a connecting tip between the source/drain and the channel, in order to induce high-field points near the channel and improve the total external resistance by lowering the source/drain-channel link-up resistance, in a known manner. According to one aspect of the invention, the shaped extension region is obtained by etching and regrowth, or amorphizing followed by etching and regrowth, or similar approaches. Semiconductor devices are provided that comprise a field effect transistor (FET) structure having a gate stack on a silicon substrate that has a silicon layer, such as bulk wafers or Silicon-On-Insulator (SOI) wafers, wherein the field effect transistor structure comprises at least a channel layer formed below said gate stack. The channel layer comprises one or more etched extension regions. The extension region contains an epitaxially grown dopant.

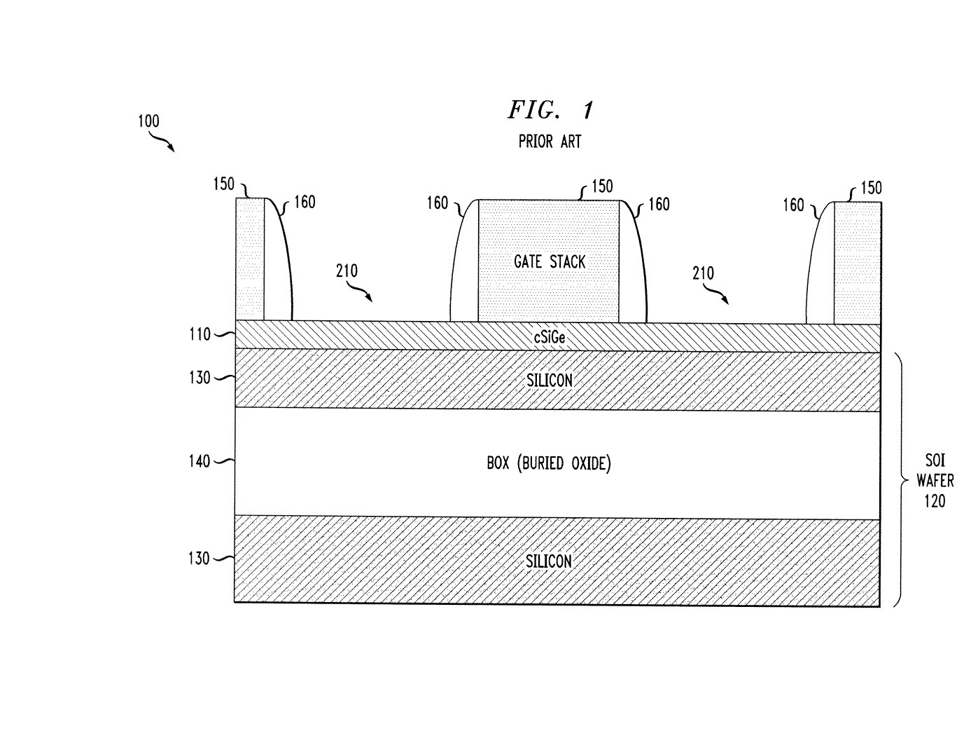

FIG. 1 illustrates a cross-sectional side view of a conventional, commercially available p-channel MOSFET (pFET) structure 100 in which a silicon germanium (SiGe) layer 110 is formed above a Silicon-On-Insulator (SOI) wafer 120. The exemplary pFET structure 100 of FIG. 1 is processed in accordance with the present invention to obtain the disclosed shaped extension region. While the first exemplary method is illustrated using a CMOS structure 100 formed on an SOI wafer, the present invention be employed with any CMOS structure 100 formed on a silicon substrate having a silicon layer.

In the exemplary structure 100 of FIG. 1, the SiGe layer 110 is deposited on the SOI wafer 120 for function control of a gate stack 150, prior to formation of the gate stack, in a known manner. As used herein, the term “channel layer” is used to indicate the layer immediately below the gate stack 150, in a known manner. In particular, the SiGe layer 110 may cause a stress in the SOI wafer 120 that improves pFET performance, in a known manner. It is noted that the SiGe layer 110 causes stress in the silicon substrate, but the SiGe layer 110 may be strained from the underlying silicon substrate. The gate stack 150 can be comprised of, for example, a gate dielectric layer and a gate conductor layer. As is known in the art, the exact composition of the gate stack 150 may be altered to optimize transistor performance. Spacers 160 are provided on the sidewalls of the gate stacks 150. The spacers 160 are typically comprised of an oxide, nitride or oxynitride material, including combinations and multilayers thereof. The spacers 160 may serve to protect the sidewalls of the gate stack 150 during subsequent processing, in a known manner.

For a more detailed discussion of suitable pFET CMOS structures 100 and corresponding fabrication techniques, see, for example, U.S. Pat. No. 7,569,434 and United States Published Patent Application Nos. 2006/0145264, 2008/0164491, and 2010/0224938, each assigned to the assignee of the present invention and incorporated by reference herein. As shown in FIG. 1, the exemplary SOI wafer 120 is comprised of one or more silicon substrate layers 130 and a buried oxide (BOX) layer 140.

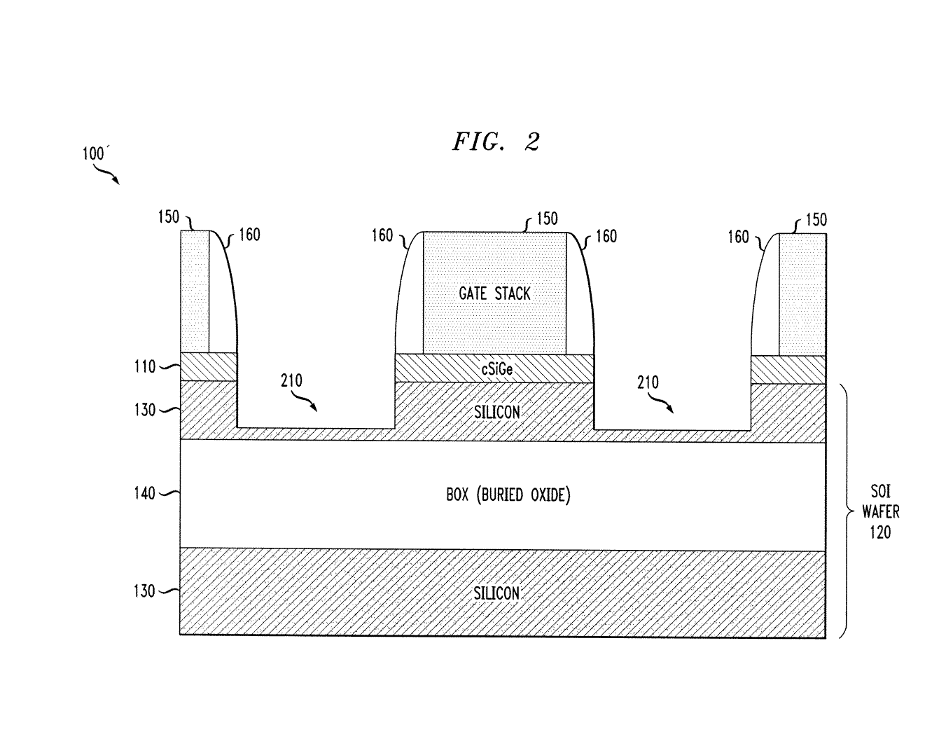

FIG. 2 illustrates a cross-sectional view along the device length of the exemplary pFET structure 100 of FIG. 1, following a step of a first exemplary method of forming an improved pFET structure. In particular, FIG. 2 illustrates trenches 210 being formed in the pFET structure 100 of FIG. 1 in accordance with an embodiment of the present invention. As shown in FIG. 2, the SiGe layer 110 of the pFET structure 100 may be exposed to a reactive ion etching (RIE) or another suitable process to form shallow trenches 210 in the region below the spacers 160. A reactive ion etching (RIE) process or another suitable process will remove the exposed portions of the SiGe layer 110 until at least a portion of the top silicon layer 130 is exposed. The RIE process stops after reaching the desired trench depth, in a known manner. In the exemplary SOI-based structures, a portion of the Si must remain above the BOX layer 140 to start epitaxial growth.

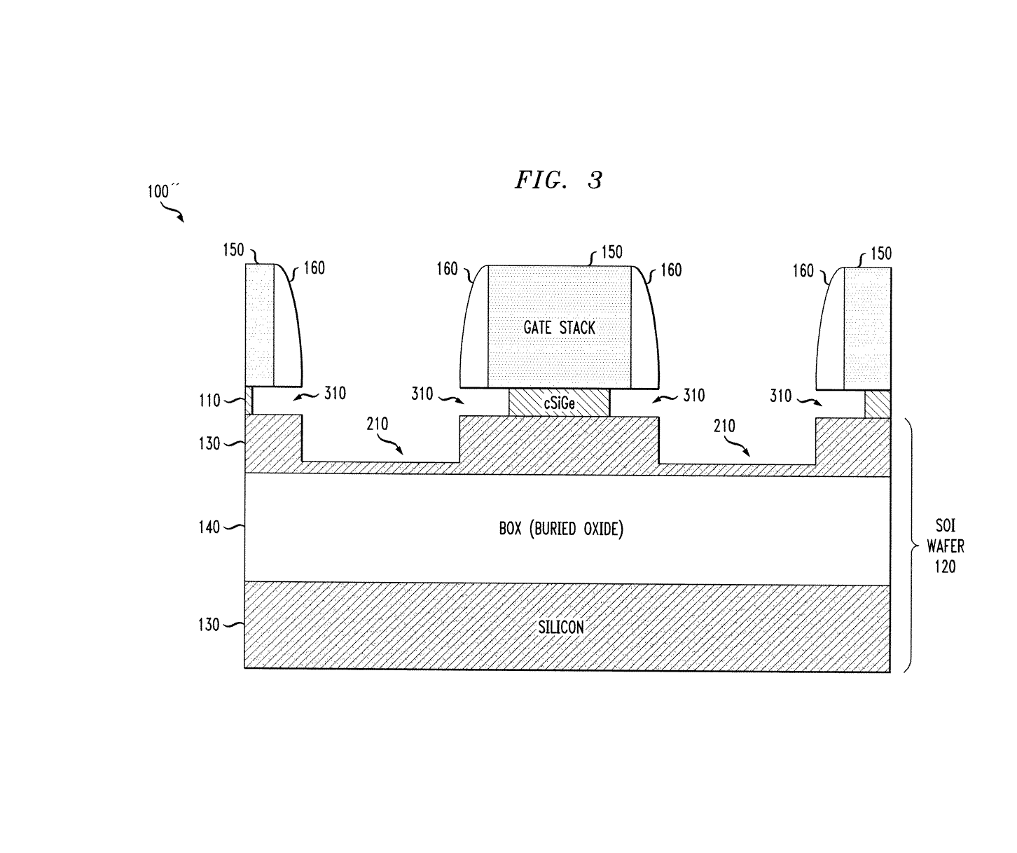

FIG. 3 illustrates a cross-sectional view of the exemplary pFET structure 100′ of FIG. 2, following a subsequent step of the first exemplary method of forming an improved pFET structure. In particular, FIG. 3 illustrates extension regions 310 being formed in the pFET structure 100′ of FIG. 2 in accordance with an embodiment of the present invention. As shown in FIG. 3, the extension regions 310 are etched in the SiGe layer 110 below the gate stack 150. The etchant selectively removes the SiGe under the spacer regions and may be, for example, HCl, Chlorine, Fluorine, SF6 and other echant gases and mixtures of thereof. A timed etching process may be performed to control the amount/distance of SiGe material that is removed from layer 110 below the gate stack 150. In a further variation, wet etch processes can be employed. Moreover, the etching process can be controlled to ensure that a sufficient amount of SiGe material remains in the layer 110 below the gate stack 150 to ensure that the integrity of the gate stack 150 is not compromised. For example, the gate stack 150 should not be separated from the SiGe layer 110. The thickness of the recess regions 310 may be limited to the thickness of the SiGe on top of the silicon substrate. The depth under the gate stack (lateral distance) can be controlled by the timing of the etch, as discussed above.

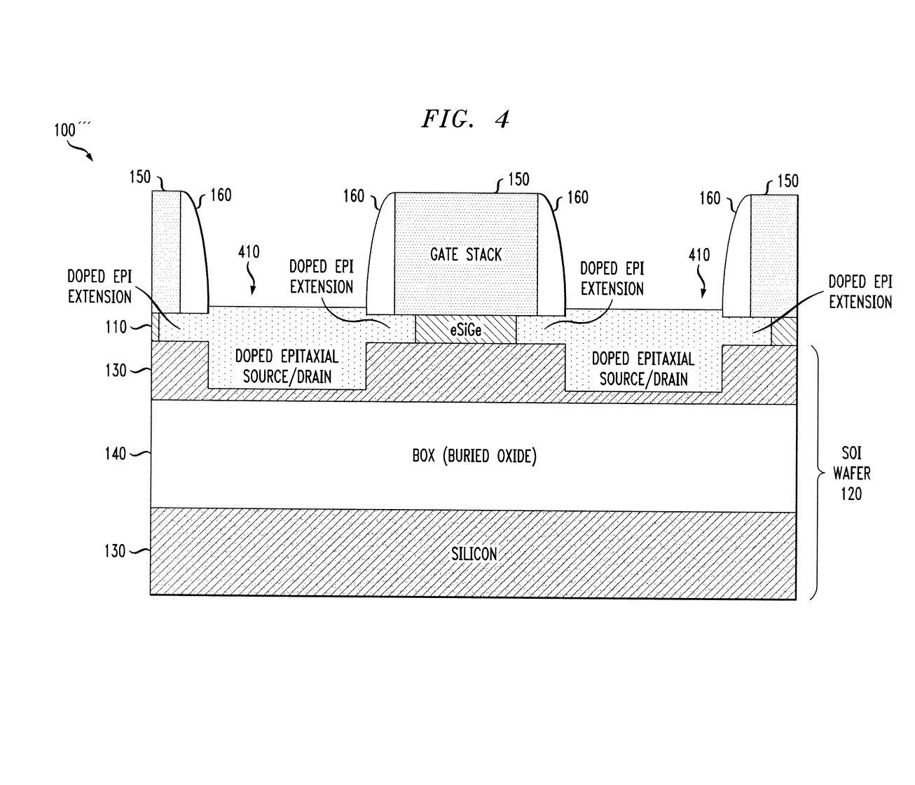

FIG. 4 illustrates a cross-sectional view of the pFET structure 100″ of FIG. 3, following a subsequent step of the first exemplary method of forming an improved pFET structure. In particular, FIG. 4 illustrates the epitaxial growth of the desired doped extension regions 410 in the pFET structure 100″ of FIG. 3 in accordance with an embodiment of the present invention.

An epitaxy process may be employed to form the in-situ doped extension region 410 in the extension regions 310 created by the step shown in FIG. 3. The formed doped epitaxial extension region 410 is combined with a growth of a strained source-drain epitaxy in the trench 210. In a further variation, the doped epitaxial extension region 410 can be combined with an unstrained source-drain epitaxy in the trench 210, such as Boron-doped Silicon. In addition, the strained or unstrained source-drain epitaxy (or Silicon for subsequent implantation) are grown within the etched trench region 210. The epitaxy process may be performed, for example, directly after the forming of the extension regions 310 using the same tool and same process or after external wet etch in another tool. In this manner, the extension dopant in the indicated portions of the layer 110 is replaced with the epitaxy dopant, not an ion implantation dopant as with conventional techniques.

The epitaxy dopant is positioned below the gate stack 150 in the channel region, where it is needed. In addition, the strained or unstrained source-drain epitaxy are grown within the etched trench region 210. The dopant materials may comprise, for example, an acceptor dopant, such as Boron, that can be incorporated in-situ with the epitaxial growth process.

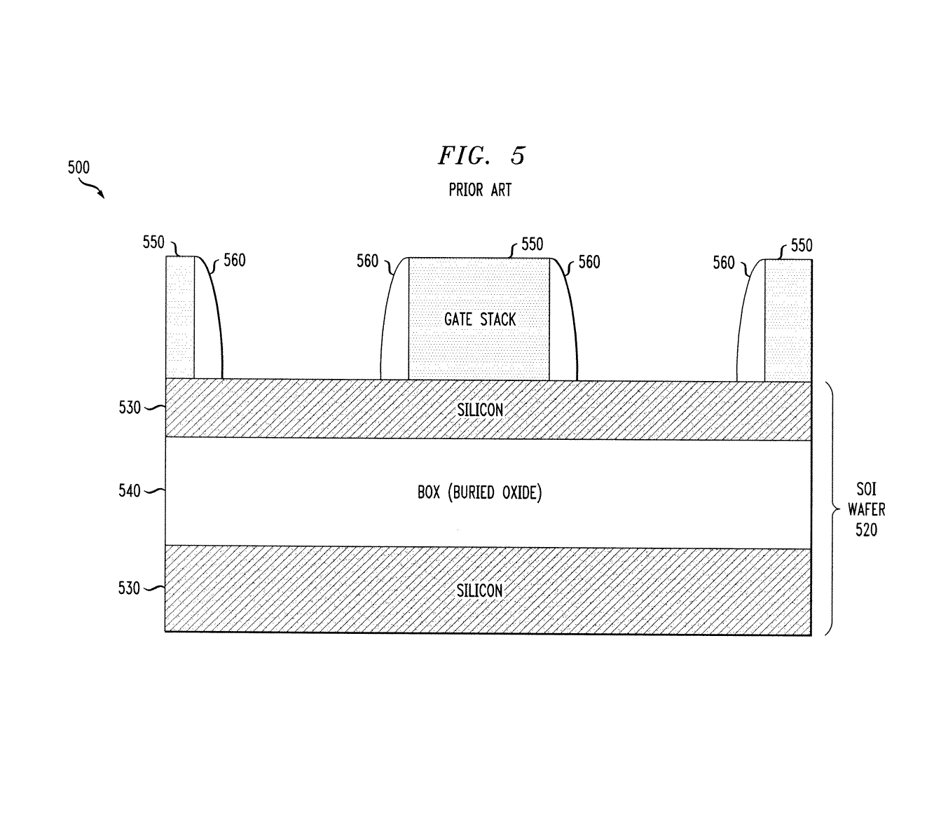

FIG. 5 illustrates a cross-sectional side view of a conventional, alternate p-channel MOSFET (pFET) structure 500. Unlike the pFET structure 100 of FIG. 1, the exemplary pFET structure 500 of FIG. 5 does not contain a SiGe layer 110 (or another silicon layer) above the wafer 520. Rather, as discussed hereinafter, the gate stack 550 is formed directly on the silicon surface of the SOI wafer 520. While the second exemplary method is illustrated using a CMOS structure 100 formed on an SOI wafer, it is again noted that the present invention be employed with any CMOS structure 100 formed on a silicon substrate having a silicon layer.

The techniques discussed in conjunction with FIGS. 5-11 can also be applied to nFET structures, as would be apparent to a person of ordinary skill in the art.

The gate stack 550 can again be comprised of, for example, a gate dielectric layer and a gate conductor layer. As is known in the art, the exact composition of the gate stack 550 may be altered to optimize transistor performance. Spacers 560 are provided on the sidewalls of the gate stacks 550, in a similar manner to FIG. 1. The spacers 560 are typically comprised of an oxide, nitride or oxynitride material, including combinations and multilayers thereof. The spacers 560 may serve to protect the sidewalls of the gate stack 550 during subsequent processing, in a known manner.

As shown in FIG. 5, the exemplary SOI wafer 520 is again comprised of one or more silicon substrate layers 530 and a buried oxide (BOX) layer 540. As discussed hereinafter, the exemplary pFET structure 500 of FIG. 5 is processed in accordance with the present invention to obtain the disclosed shaped extension region. While the exemplary technique is discussed in conjunction with the pFET structure 500 of FIG. 5, the present invention can also be applied to provide improved nFET CMOS device structures that employ a shaped extension region, as would be apparent to a person of ordinary skill in the art.

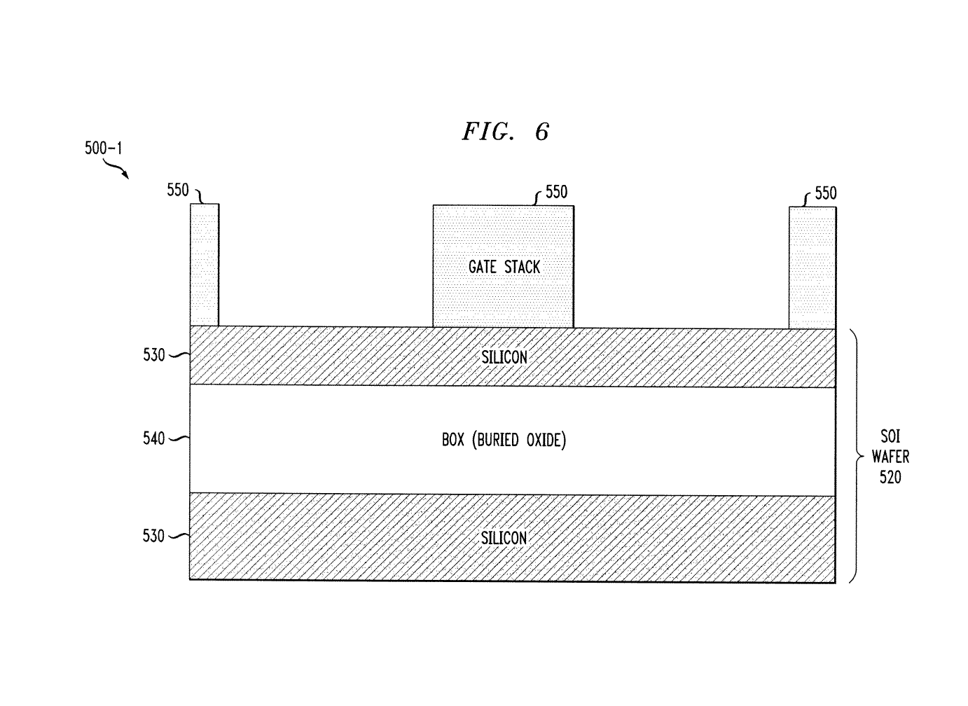

FIG. 6 illustrates a cross-sectional view of the pFET structure 500 of FIG. 5, following a step of a second exemplary method of forming an improved pFET structure. In particular, FIG. 5 illustrates a modified pFET structure 500-1 where the spacers 560 have been removed from the pFET structure 500 of FIG. 5, in accordance with an embodiment of the present invention. The spacers 560 can be removed, for example, using well-known etching processes.

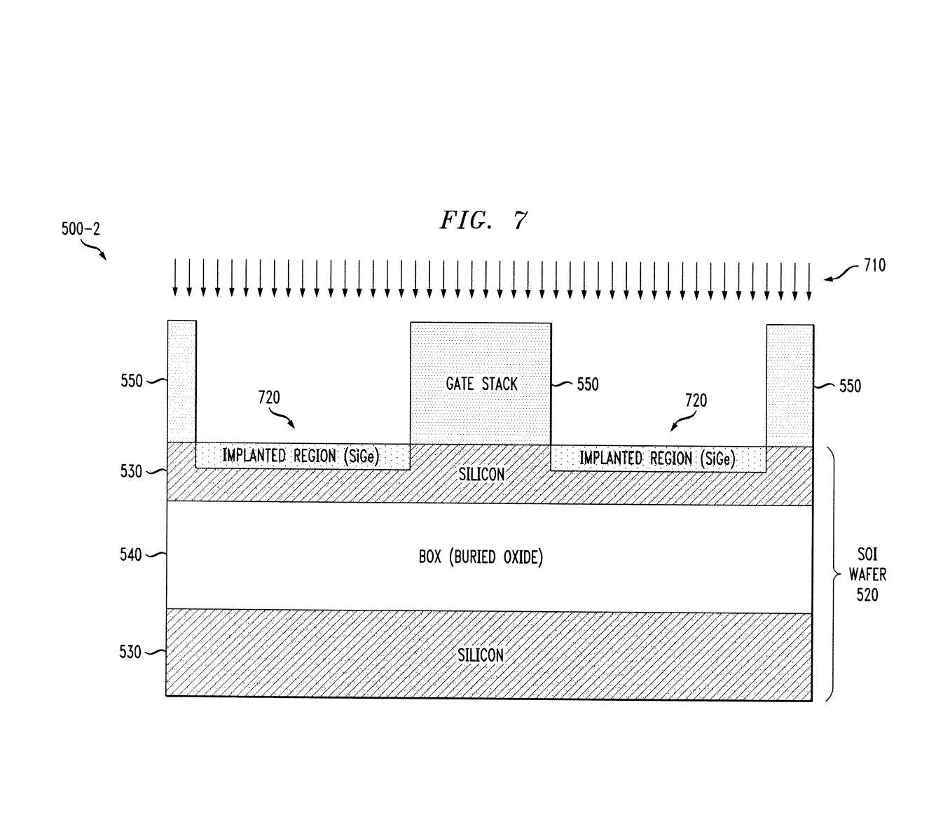

FIG. 7 illustrates a cross-sectional view of the pFET structure 500-1 of FIG. 6, following a subsequent step of the second exemplary method of forming an improved pFET structure. In particular, FIG. 7 illustrates a Germanium (Ge) ion implantation process 710 where Ge is implanted in the top silicon layer 530 to form a modified pFET structure 500-2 having an implanted region 720 of subsequent formed Silicon Germanium in the pFET structure 500-1 of FIG. 6 in accordance with an embodiment of the present invention. It is noted that a hardmask (not shown) can optionally be positioned on the gate stack 550 to prevent Ge implantation in the gate stack 550. In one variation, the implanted region can be defective and therefore etches even faster and be more selective.

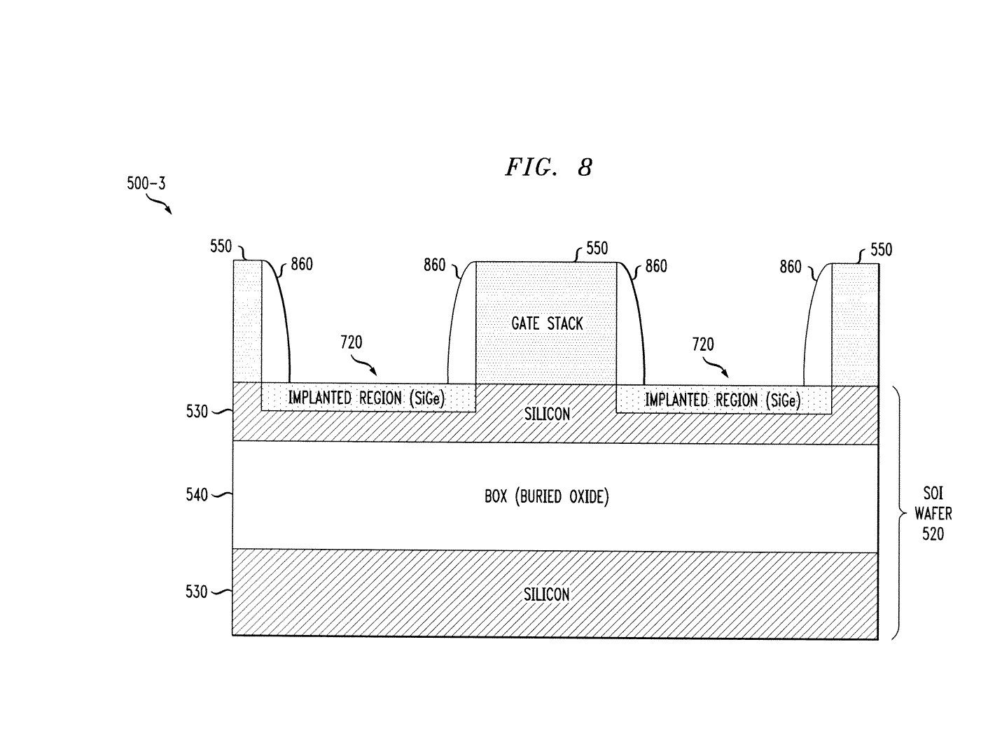

FIG. 8 illustrates a cross-sectional view of the pFET structure 500-2 of FIG. 7, following a subsequent step of the second exemplary method of forming an improved pFET structure. In particular, FIG. 8 illustrates spacers 860 being re-formed on the modified pFET structure 500-2 of FIG. 7, in a known manner, to form a further modified pFET structure 500-3 in accordance with an embodiment of the present invention. As shown in FIG. 8, the removed spacers 860 extend partially over the implanted SiGe region 720.

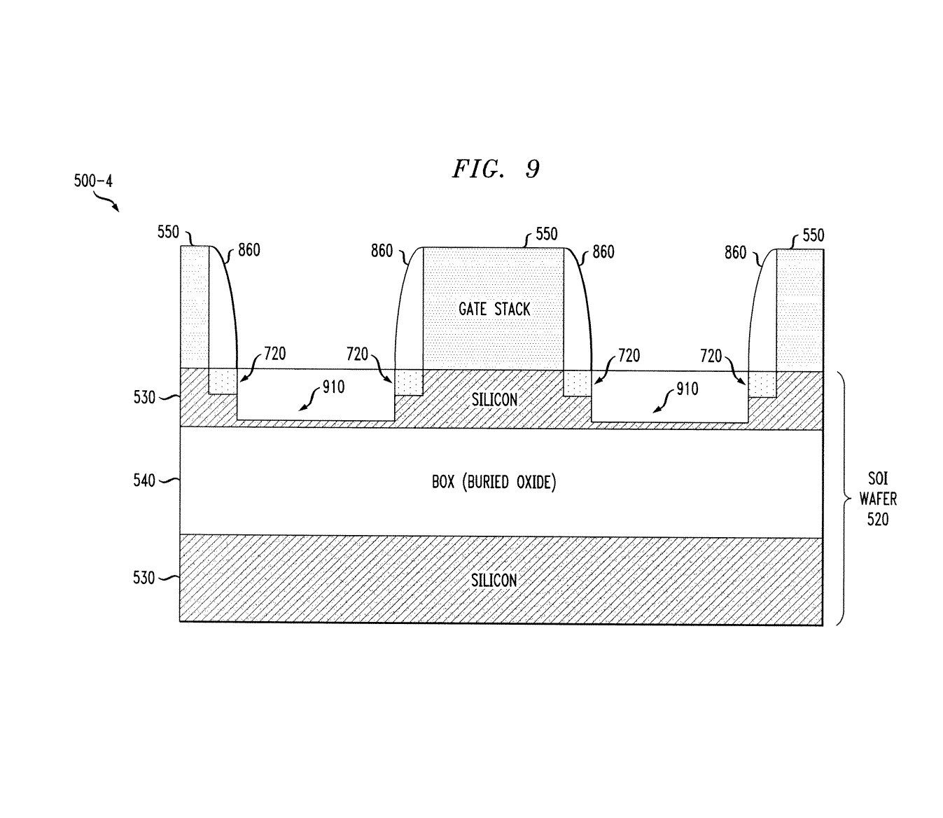

FIG. 9 illustrates a cross-sectional side view of the pFET structure 500-3 of FIG. 8, following a subsequent step of the second exemplary method of forming an improved pFET structure. In particular, FIG. 9 illustrates a portion of the implanted SiGe region 720 being removed from the modified pFET structure 500-3 of FIG. 8, using an RIE process or any other suitable process, to form a further modified pFET structure 500-4 in accordance with an embodiment of the present invention.

As shown in FIG. 9, the SiGe region 720 of the exemplary pFET structure 500-3 of FIG. 8 may be exposed to a reactive ion etching (RIE) or another suitable process to form shallow trenches 910 in the region below the spacers 560, in a similar manner to FIG. 2. The exemplary RIE process will remove the exposed portions of the SiGe region 720 until at least a portion of the top silicon layer 530 is exposed.

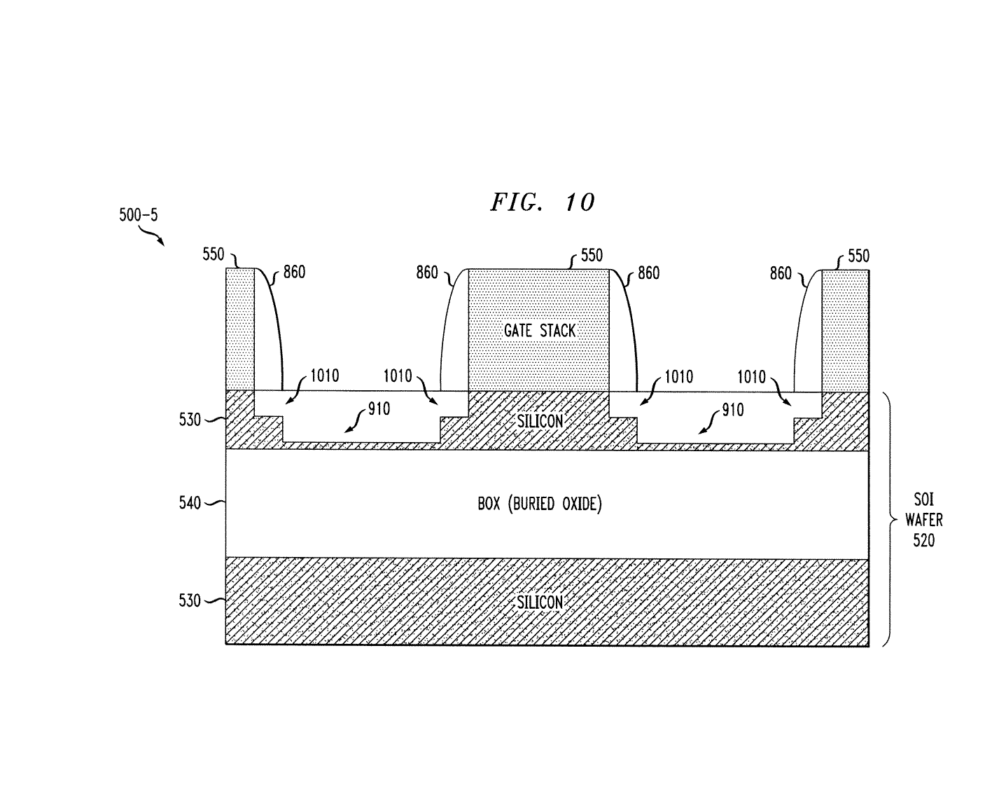

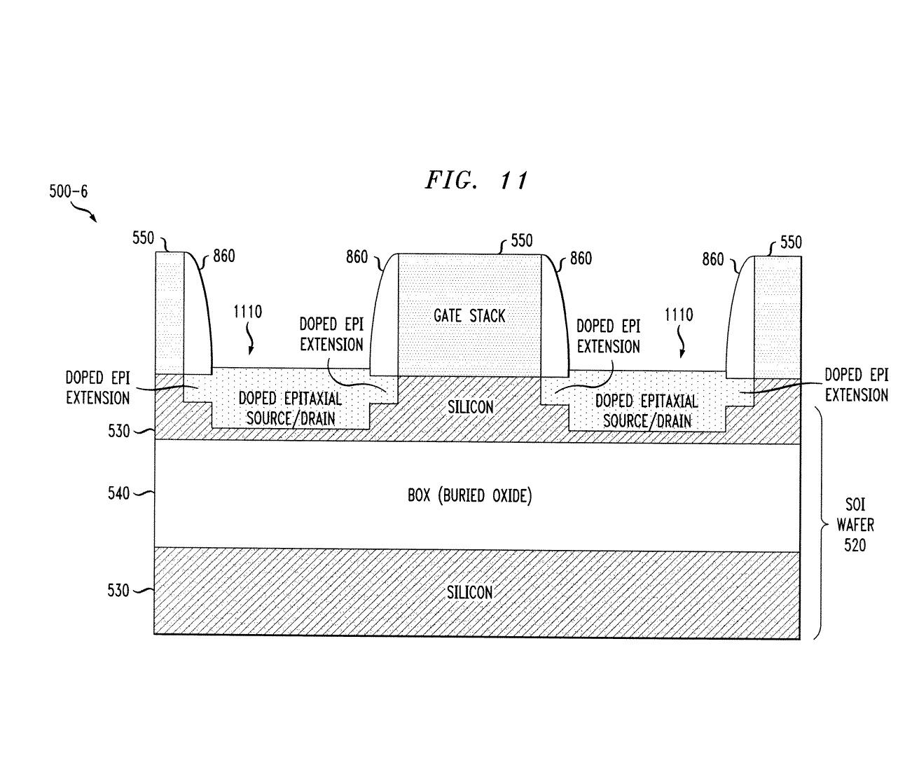

FIG. 10 illustrates a cross-sectional view of the pFET structure 500-4 of FIG. 9, following a subsequent step of the second exemplary method of forming an improved pFET structure. In particular, FIG. 10 illustrates extension regions 1010 being formed in the pFET structure 500-4 of FIG. 9 in accordance with an embodiment of the present invention, in a similar manner to FIG. 3. As shown in FIG. 10, the extension regions 1010 are etched in the remaining portions of the SiGe region 720 below the spaces 560 and gate stack 550. The etchant may be, for example, HCl, Chlorine, Fluorine, SF6 and other etchant gases and mixtures of thereof. A wet etch process can also be employed. The etch process is self-limiting, until all implanted SiGe material from the extension region is removed. Overetching should be avoided. The gate stack 550 should not be separated from the silicon layer 530. FIG. 11 illustrates a cross-sectional side view of the pFET structure 500-5 of FIG. 10, following a subsequent step of the second exemplary method of forming an improved pFET structure. In particular, FIG. 10 illustrates the epitaxial growth of the desired doped extension regions 1110 in the pFET structure 500-5 of FIG. 10 in accordance with an embodiment of the present invention, in a similar manner to FIG. 4.

An epitaxy process may be employed to form the doped extension region 1110 in the extension regions 1010 created by the step shown in FIG. 10. The formed doped epitaxial extension region 1110 is combined with a growth of a strained source-drain epitaxy in the trench 910. The epitaxy process may be performed, for example, directly after the forming of the extension regions 1010 using the same tool and same process. In this manner, the implant dopant in the indicated portions of the layer 530 is replaced with the epitaxy dopant. The epitaxy dopant is positioned below the gate stack 150 in the channel region, where it is needed. In addition, the strained or unstrained source-drain epitaxy (or Silicon for subsequent implantation) are grown within the etched trench region 910. The unstrained source-drain epitaxy can be, for example, Boron-doped Silicon, or Phosphorus, Antimony or Arsenic doped Silicon in the case of an nFET structure. The dopant materials may comprise, for example, an acceptor dopant, such as Boron, that can be incorporated in-situ with the epitaxial growth process. The disclosed shaped extension regions provide (i) shallow and steep junctions by a low-temperature selective epitaxy process, that is not damaging to the masking materials; (ii) suppression of dopant diffusion by eliminating anneals usually needed after implantation; (iii) reduced damage to the crystal near the active channel; (iv) strains provided by the source/drain stressor fill to be efficiently applied to the channel, if strain is desired; (v) reduced link-up resistance; (vi) all of which enable scaling beyond 22 nm.

The foregoing description discloses only exemplary embodiments of the invention. Modifications of the above disclosed structures and method which fall within the scope of the invention will be readily apparent to those of ordinary skill in the art. For example, while the exemplary second technique is discussed in conjunction with an exemplary pFET structure of FIGS. 5-11, the present invention can also be applied to provide improved nFET CMOS device structures that employ a shaped doped extension region, as would be apparent to a person of ordinary skill in the art.

Accordingly, while the present invention has been disclosed in connection with exemplary embodiments thereof, it should be understood that other embodiments may fall within the spirit and scope of the invention, as defined by the following claims.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A semiconductor device, comprising:
a field effect transistor (FET) structure having a gate stack on a silicon substrate, wherein said field effect transistor structure comprises at least a channel layer formed below said gate stack;
one or more etched extension regions in said channel layer, said extension regions containing an epitaxially grown dopant.

2. The semiconductor device of claim 1, wherein said silicon substrate comprises one or more of a bulk wafer and a Silicon-On-Insulator (SOI) wafer.

3. The semiconductor device of claim 2, wherein said channel layer comprises a silicon germanium (SiGe) region formed above said silicon substrate and below said gate stack.

4. The semiconductor device of claim 3, wherein said SiGe region is created by implanting germanium in a silicon layer in said silicon substrate.

5. The semiconductor device of claim 3, wherein said SiGe region is created epitaxially.

6. The semiconductor device of claim 1, wherein said channel layer is a first layer below said gate stack.

7. The semiconductor device of claim 1, wherein said epitaxially grown dopant is combined in said extension region with a growth of a source-drain epitaxy in a trench.

8. The semiconductor device of claim 1, wherein said semiconductor device is embodied on a CMOS circuit and wherein the FET structure comprises one or more of a pFET structure and an nFET structure.

9. A method of forming a semiconductor device, comprising:
obtaining a field effect transistor (FET) structure having a gate stack on a silicon substrate, wherein said field effect transistor structure comprises a channel layer formed below said gate stack;
etching one or more extension regions in said channel layer at least partially below said gate stack; and
epitaxially growing a dopant in said extension region.

10. The method of claim 9, wherein said etching step comprises a reactive ion etching (RIE) process.

11. The method of claim 9, wherein said etching step employs an etchant material comprising one or more of HCl, Chlorine, Fluorine, SF6 and mixtures thereof.

12. The method of claim 9, further comprising the step of combining said epitaxially grown dopant in said extension region with a growth of a source-drain epitaxy in a trench.

13. The method of claim 9, wherein said channel layer comprises a silicon germanium (SiGe) region formed above said silicon substrate and below said gate stack.

14. The method of claim 13, wherein said SiGe region is created epitaxially.

15. The method of claim 13, further comprising the step of implanting germanium in a silicon layer in said silicon substrate to create said SiGe region.

16. The method of claim 15, further comprising the step of removing one or more spacers from said semiconductor device prior to said implanting step.

17. The method of claim 15, further comprising the step of forming one or more spacers on said semiconductor device following said implanting step.

18. The method of claim 9, wherein said FET structure comprises one or more of a pFET structure and an nFET structure.

19. A CMOS circuit, comprising:
a field effect transistor (FET) structure having a gate stack on a silicon substrate, wherein said field effect transistor structure comprises at least a channel layer formed below said gate stack, wherein the FET structure comprises one or more of a pFET structure and an nFET structure; and
one or more etched extension regions in said channel layer, said extension regions containing an epitaxially grown dopant.

20. The CMOS circuit of claim 19, wherein said silicon substrate comprises one or more of a bulk wafer and a Silicon-On-Insulator (SOI) wafer.

21. The CMOS circuit of claim 20, wherein said FET structure comprises a pFET structure and said channel layer comprises a silicon germanium (SiGe) region formed above said silicon substrate and below said gate stack.

22. The CMOS circuit of claim 19, wherein said channel layer is a first layer below said gate stack.

23. The CMOS circuit of claim 19, wherein said epitaxially grown dopant is combined in said extension region with a growth of a source-drain epitaxy in a trench.
